(19) United States
(12) Patent Application Publication
(10) Pub. No.: US 2024/0147627 A1
(43) Pub. Date: May 2, 2024

(54) METHOD FOR MANUFACTURING SUBSTRATE WITH CONDUCTIVE PATTERN ATTACHED THERETO

(71) Applicant: PANASONIC INTELLECTUAL PROPERTY MANAGEMENT CO., LTD., Osaka (JP)

(72) Inventors: Tomohiro FUKAO, Osaka (JP); Tomoaki SAWADA, Osaka (JP); Kyosuke MICHIGAMI, Hyogo (JP)

(73) Assignee: PANASONIC INTELLECTUAL PROPERTY MANAGEMENT CO., LTD., Osaka (JP)

(21) Appl. No.: 18/532,011

(22) Filed: Dec. 7, 2023

Related U.S. Application Data
(63) Continuation of application No. PCT/JP2022/022839, filed on Jun. 6, 2022.

(30) Foreign Application Priority Data
Jun. 11, 2021 (JP) 2021-098100

(51) Int. Cl. H05K 3/00; H05K 1/02; H05K 3/18

(52) U.S. Cl. CPC H05K 3/0058; H05K 1/0283; H05K 3/188; H05K 2201/0212; H05K 2203/0323

(57) ABSTRACT

One aspect of the present invention relates to a method for manufacturing a substrate with a conductive pattern, the method including: a base forming step of forming a plating base in a desired pattern on at least a portion of one surface of a stretchable substrate, wherein the stretchable substrate has a tensile modulus at 20° C. of 0.1 MPa or more and 500 MPa or less, an elongation at break of 100% or more and 1000% or less, and a storage modulus at 250° C. of 0.1 MPa or more; a bending step of bending the stretchable substrate; and a conductive pattern forming step of plating the plating base after performing the bending step to form a conductive pattern on the stretchable substrate.

### FIELD OF INVENTION

The present invention relates to a method for manufacturing a substrate with a conductive pattern, particularly a method for manufacturing a substrate with a conductive pattern having a curved surface.

### BACKGROUND ART

Devices and conductive materials used in the electronics field, particularly in various interfaces such as sensors, displays, and artificial skin for robots are increasingly demanded to exhibit mountability and shape followability. There is a growing demand for flexible devices that can be disposed on curved or uneven surfaces or can be freely deformed depending on the application.

On the other hand, a method for forming a circuit or wiring on a three-dimensional object having a curved surface has also been studied. For example, Patent Literature 1 discloses a method for manufacturing a three-dimensional wiring board, the method including: a preparation step of preparing a resin film having an elongation at break of 50% or more; a first metal film forming step of forming a first metal film on a surface of the resin film; a pattern forming step of performing patterning on the first metal film by photolithography to form a desired pattern; a three-dimensional molding step of performing three-dimensional molding by heating and pressurizing the resin film; and a second metal film forming step of forming a second metal film on the first metal film having a pattern formed thereon; wherein, in the first metal film forming step, the first metal film is formed in a porous state by depositing a metal in a particle state and regulating a film thickness.

Also Patent Literature 2 discloses a method for producing a three-dimensional conductive pattern structure having a conductive pattern formed on the surface of a three-dimensional structure, which comprises the following steps a) to d): a) a modified-pattern forming step wherein a material for three-dimensional molding having a polyimide resin surface in at least a part thereof is subjected to pattern printing on the polyimide resin surface using a modifier to produce a material for three-dimensional molding on which a modified-pattern with cloven imide rings is formed; b) a plating-catalytic-active pattern forming step wherein, on the pattern-formed portion of the material for three-dimensional molding on which a modified-pattern is formed which is obtained by the step a), metal ions having plating catalytic activity are adsorbed, and subsequently the metal ions are reduced to produce a material for three-dimensional molding on which a pattern having plating catalytic activity is formed; c) a three-dimensional molding step wherein the material for three-dimensional molding on which a pattern having plating catalytic activity is formed which is obtained by the step b) is three-dimensionally molded to produce a three-dimensional structure on which a pattern having plating catalytic activity is formed; and d) an electroless plating step wherein the three-dimensional structure on which a pattern having plating catalytic activity is formed which is obtained by the step c) is subjected to electroless plating to form a conductive pattern to produce a three-dimensional conductive pattern structure.

However, in the techniques described in Patent Literature 1 and 2, a polyimide resin is used as a substrate, and there is a problem that a large amount of energy is required for the three-dimensional molding step. In addition, it is difficult to say that the flexibility is sufficient, and in a case where the object on which a circuit is to be formed is made of a soft material, there is a possibility that the shape and the touch feeling of the object are impaired or the circuit is broken by an expansion/contraction operation.

The present invention has been devised in view of such circumstances, and it is an object of the present invention to provide a method for manufacturing a circuit board by which a circuit or wiring that is hardly broken can be formed simply and easily on a three-dimensional structure (an object on which a circuit is to be formed) having projections and recesses (bent portions).

Patent Literature 1: WO 2016/208090 A

Patent Literature 2: WO 2014/168220 A

### SUMMARY OF INVENTION

As a result of intensive studies, the present inventors have found out that the problems can be solved by the following configuration, and completed the present invention by conducting further studies based on this finding.

That is, a method for manufacturing a substrate with a conductive pattern relating to one aspect of the present invention includes:
a base forming step of forming a plating base in a desired pattern on at least a portion of one surface of a stretchable substrate, wherein the stretchable substrate has a tensile modulus at 20° C. of 0.1 MPa or more and 500 MPa or less, an elongation at break of 100% or more and 1000% or less, and a storage modulus at 250° C. of 0.1 MPa or more;
a bending step of bending the stretchable substrate; and
a conductive pattern forming step of plating the plating base after performing the bending step to form a conductive pattern on the stretchable substrate.

A method for manufacturing a substrate with a conductive pattern according to another aspect of the present invention includes:
a base forming step of forming a plating base on at least a portion of one surface of a stretchable substrate, wherein the stretchable substrate has a tensile modulus at 20° C. of 0.1 MPa or more and 500 MPa or less, an elongation at break of 100% or more and 1000% or less, and a storage modulus at 250° C. of 0.1 MPa or more;
a bending step of bending the stretchable substrate;
a metal layer forming step of plating the plating base after performing the bending step to form a metal layer; and
a conductive pattern forming step of etching the metal layer to form a conductive pattern.

### BRIEF DESCRIPTION OF THE DRAWINGS

FIGS. 1A to 1C are schematic cross-sectional views illustrating a method for manufacturing a substrate with a conductive pattern according to one embodiment of the present invention.

FIGS. 2A to 2E are schematic cross-sectional views illustrating a method for manufacturing a substrate with a conductive pattern according to another embodiment of the present invention.

### DETAILED DESCRIPTION

### Method for Manufacturing Substrate with Conductive Pattern

The method for manufacturing a substrate with a conductive pattern of the present embodiment includes: a base forming step of forming, on at least a portion of one surface of a stretchable substrate (hereinafter, also simply referred to as a “substrate”), a plating base in a desired pattern, the stretchable substrate having a tensile modulus at 20° C. of 0.1 MPa or more and 500 MPa or less, an elongation at break of 100% or more and 1000% or less, and a storage modulus at 250° C. of 0.1 MPa or more; a bending step of bending the stretchable substrate; and a conductive pattern forming step of plating the plating base after performing the bending step to form a conductive pattern on the stretchable substrate.

The above configuration makes it possible to provide a method for manufacturing a substrate with a conductive pattern by which method a circuit, wiring, a heating wire, or the like that is hardly broken can be formed simply and easily on a three-dimensional structure (an object on which a conductive pattern is to be formed) having projections and recesses (bent portions).

Hereinafter, some embodiments according to the present invention will be specifically described with reference to drawings and the like, but the present invention is not limited thereto.

### Substrate

First, a substrate used in the present embodiment will be described. The substrate used in the present embodiment is a stretchable substrate having a tensile modulus at 20° C. of 0.1 MPa or more and 500 MPa or less, an elongation at break of 100% or more and 1000% or less, and a storage modulus at 250° C. of 0.1 MPa or more. Since the substrate of the present embodiment has flexibility even at room temperature and can follow projections and recesses of a three-dimensional shape, it is possible to form a substrate with a conductive pattern on objects with various shapes having a bent portion or the like. In addition, there is an advantage that even if the object is a soft material, the shape and tactile sensation of the object on which a conductive pattern is to be formed are not impaired, the resulting circuit, wiring, a heating wire, or the like is also resistant to breakage, and for example, the circuit or the like is not broken by the expansion/contraction motion.

In the present embodiment, a sample cut into a size of 90 mm*5.5 mm was attached to a universal tester (AGS-X manufactured by Shimadzu Corporation), a test was performed at a tensile speed of 500 mm/min, and a tensile modulus was calculated from a stress at an elongation of from 1.0% to 5.0%.

A more preferable range of the tensile modulus of the substrate of the present embodiment is 1.0 MPa or more and 100 MPa or less. This offers an advantage that the handleability of the substrate is good and sufficient followability to projections and recesses is obtained.

In addition, since the substrate of the present embodiment has an elongation at break of 100% or more and 1000% or less, it is possible to control breaking when the substrate is laminated on a three-dimensional structure and a bent portion of a mold described later. The elongation at break is an index (elongation rate) indicating flexibility in the present embodiment, and can be obtained by attaching a sample obtained by cutting a substrate sample into a size of 90 mm*5.5 mm to a universal tester (AGS-X manufactured by Shimadzu Corporation), performing a test at a tensile speed of 500 mm/min, and measuring the elongation rate when the sample breaks with the tester.

Furthermore, the substrate of the present embodiment has a storage modulus at 250° C. of 0.1 MPa or more. Owing to this, the substrate can ensure sufficient heat resistance, and is superior in component mountability without being deteriorated even when a component is mounted. The storage modulus in the present embodiment is a value that can be measured by the method described in Examples described later.

The substrate of the present embodiment is not particularly limited as long as the substrate is made of a material having a tensile modulus, an elongation at break, and a storage modulus within the above ranges, but preferably contains, for example, a thermosetting resin. When the substrate in the present embodiment contains a thermosetting resin, the substrate exhibits high heat resistance, and can be a substrate that hardly melts or thermally decomposes even in a high-temperature atmosphere at the time of mounting an electronic component, for example.

As the thermosetting resin, a thermosetting resin commonly used as an insulating layer of an electronic substrate can be used.

The substrate of the present embodiment is preferably formed of, for example, a cured or semi-cured product of a resin composition containing a thermosetting resin, but the composition of the resin composition is not particularly limited as long as the tensile modulus of the substrate at 20° C. is in the above-described range.

For example, the resin composition of the present embodiment preferably contains an epoxy resin as the thermosetting resin. Furthermore, the resin composition preferably contains a curing agent. As a result, it is possible to obtain a substrate that has sufficient heat resistance and can withstand heat applied when a component is mounted by a reflow process. When the uncured resin composition is laminated on an object on which a conductive pattern is to be formed, which is described later, and then cured, the substrate can be easily integrated with the object on which a conductive pattern is to be formed without using an adhesive or the like.

Examples of the thermosetting resin include without any particular limitations, in addition to the epoxy resin, thermosetting resins such as a phenol resin, a polyimide resin, a urea resin, a melamine resin, an unsaturated polyester, and a urethane resin, but it is preferable to use an epoxy resin among them.

Examples of the epoxy resin specifically include a bisphenol A type epoxy resin, a bisphenol F type epoxy resin, a bisphenol S type epoxy resin, an aralkyl epoxy resin, a phenol novolac type epoxy resin, an alkylphenol novolac type epoxy resin, a biphenol type epoxy resin, a naphthalene type epoxy resin, a dicyclopentadiene type epoxy resin, an epoxidized product of a condensate of a phenol and an aromatic aldehyde having a phenolic hydroxy group, triglycidyl isocyanurate, and an alicyclic epoxy resin. These may be used singly or in combination of two or more kinds thereof depending on the situation.

The epoxy resin is more preferably, for example, an epoxy resin containing two or more epoxy groups in one molecule and having a molecular weight of 500 or more. As such an epoxy resin, a commercially available epoxy resin may be used, and examples thereof include JER1003 (manufactured by Mitsubishi Chemical Corporation, molecular weight: 1300, bifunctional), EXA-4816 (manufactured by DIC Corporation, molecular weight: 824, bifunctional), YP50 (manufactured by Nippon Steel & Sumikin Chemical Co., Ltd., molecular weight: 60000 to 80000, bifunctional), and PMS-14-67 (manufactured by Nagase ChemteX Corporation, molecular weight: 300,000, polyfunctional). In addition, epoxy resins such as those recited above can be used singly or as a combination of two or more types thereof.

The curing agent is not particularly limited as long as the curing agent can act as a curing agent for the thermosetting resin as described above.

In particular, examples of curing agents able to be suitably used as curing agents for epoxy resins include phenol resins, amine-based compounds, acid anhydrides, imidazole-based compounds, sulfide resins, and dicyandiamide. A light/ultraviolet curing agent, a thermal cationic curing agent and the like can also be used. These may be used singly or in combination of two or more kinds thereof depending on the situation. The resin composition may contain a curing accelerator, as necessary. Examples of the curing accelerator include imidazole-based compounds.

When the resin composition of the present embodiment contains an epoxy resin, the epoxy resin is preferably contained in an amount of approximately 50 to 99 parts by mass based on 100 parts by mass of the total amount of the resin composition. The amount of the curing agent can be appropriately set according to the number of functional groups of the epoxy group in the epoxy resin.

Furthermore, the resin composition may contain other additives, such as a curing catalyst (a curing accelerator), a flame retardant, a flame retardant aid, a leveling agent, and a colorant, as necessary, as long as the effect of the present invention is not impaired.

The method for preparing such a resin composition is not particularly limited, and for example, the resin composition of the present embodiment can be obtained by first mixing an epoxy resin, a curing agent, a crosslinking agent, a thermosetting resin, and a solvent such that a uniform mixture is formed. The solvent to be used is not particularly limited, and for example, toluene, xylene, methyl ethyl ketone, and acetone can be used. These solvents may be used singly or in combination of two or more kinds thereof. In addition, an organic solvent for adjusting the viscosity and various additives may be further blended, as necessary.

The substrate of the present embodiment is obtained, for example, by semi-curing (B-stage) or curing (C-stage) the resin composition as described above. The timing of the semi-curing or curing may be after or before laminating on an object on which a conductive pattern is to be formed, which is described later, or before forming a base.

Specifically, for example, the substrate of the present embodiment can be formed by a method in which a resin varnish containing an organic solvent is prepared from a resin composition as described above, applied to a surface of a desired plastic film (support), and then dried. The method for applying the resin composition is not particularly limited, and examples thereof include a bar coater, a comma coater, a die coater, a roll coater, and a gravure coater.

After the application of the resin varnish, the organic solvent can be volatilized by heating from the resin layer (A-stage) containing the uncured resin composition containing the organic solvent to reduce or remove the organic solvent. When the applied resin varnish is heated under desired heating conditions, for example, at 80 to 120° C. for 1 to 120 minutes, an uncured or semi-cured (B-stage) substrate from which the organic solvent has been reduced or removed is obtained. In the present embodiment, the B-stage of the resin composition, that is, the uncured state (uncured product) or the semi-cured state (semi-cured product) is a state in which the resin composition can be further cured. For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

Further, the substrate can be cured by heating. The applied resin composition (resin varnish) is heated under desired heating conditions, for example, at 80 to 200° C. for 1 to 120 minutes to afford a substrate in a cured state (C-stage). In the present embodiment, the C-stage of the resin composition, that is, the cured state (cured product) refers to a state in which the resin is no longer melted even when heated due to progress of a curing reaction and crosslinking of the resin.

When the film-shaped resin composition is bonded to an object on which a conductive pattern is to be formed, for example, the resin composition is applied in advance to a desired plastic film (support) or the like, and a resin layer containing a resin composition before curing (A-stage) containing an organic solvent is formed on the film or a resin layer in an uncured state or a semi-cured state (B-stage) is formed on the film by heating under desired heating conditions, for example, at 80 to 120° C. for 1 to 120 minutes. Furthermore, the substrate may be cured by heating to form a cured (C-stage) substrate.

### First Embodiment

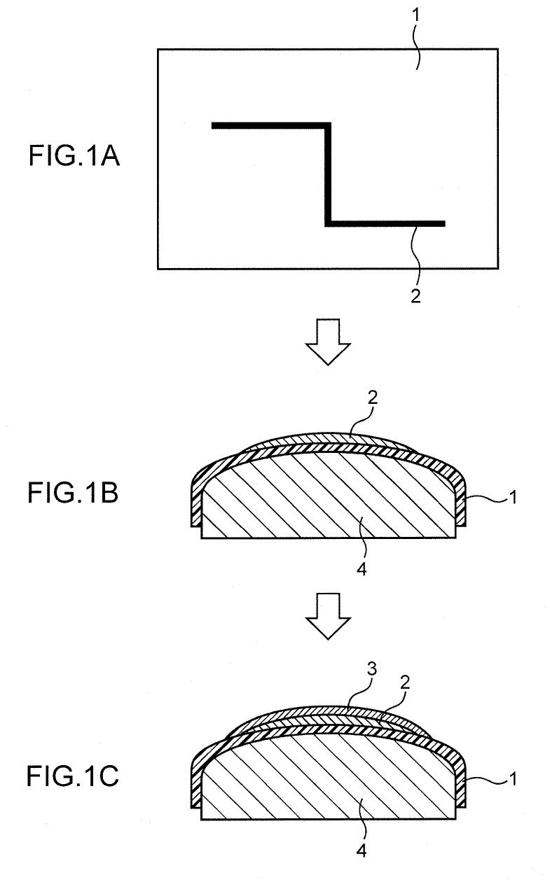

Next, one embodiment of the method for manufacturing a substrate with a conductive pattern of the present invention using the substrate as described above will be described with reference to FIG. 1. In the present description, reference numerals in the drawings denote 1: substrate, 2: plating base, 3: l plating (metal layer), 4: three-dimensional structure (object on which a conductive pattern is to be formed), 5: mold, and 6: release liner.

First, as shown in FIG. 1(A), a stretchable substrate 1 having a tensile modulus at 20° C. of 0.1 MPa or more and 500 MPa or less, an elongation at break of 100% or more and 1000% or less, and a storage modulus at 250° C. of 0.1 MPa or more is prepared, and a plating base 2 is formed on one surface of the stretchable substrate 1 (base forming step). Next, as shown in FIG. 1(B), the substrate 1 on which the plating base 2 is formed is bent (bending step). Thereafter, as shown in FIG. 1(C), for the stretchable substrate bent in the bending step, plating 3 is applied onto the plating base 2 to form a conductive pattern on the stretchable substrate (conductive pattern forming step). In the bending step, the plating base 2 follows the bent shape together with the substrate, and then the plating 3 is formed on the plating base 2, so that there is no risk of disconnection of a circuit or the like obtained by the conductive pattern. The conductive pattern formed in the present embodiment can be used as a circuit or wiring, and can also be used as, for example, a heating wire (resistance wire) for a heater.

In such a method for manufacturing a substrate with a conductive pattern according to the present embodiment, a desired circuit pattern or the like can be simply and easily formed on a bent surface of a three-dimensional structure. The method of the present embodiment is advantageous in that even if the three-dimensional structure is a soft material, the shape and tactile sensation of the object on which a conductive pattern is to be formed are not impaired, the resulting circuit or the like is also resistant to breakage, and for example, the circuit or the like is not broken by the expansion/contraction motion.

Details of each step in the first embodiment will be further described.

### Base Forming Step

The plating base forming step is a step of forming a plating base in a desired pattern shape on at least a part of one surface of the substrate as described above. With the plating base, a conductive pattern is formed on the substrate according to the shape of a desired circuit, wiring, a heating wire, or the like. The plating base may be formed in a state where the substrate is stretched or before stretching (normal state).

The plating base formation of the present embodiment means that a plating catalyst as described above is attached to the surface of the substrate. Herein, the plating catalyst has a concept including a precursor thereof.

The plating catalyst is a catalyst that is provided in advance to form a plating film only on a portion where plating (an electroless plating film) is intended to be formed in a conductive pattern forming step described later. As the plating catalyst, any catalyst known as a catalyst for electroless plating can be used without any particular limitation. In addition, a precursor of the plating catalyst may be attached in advance, and then made to generate the plating catalyst. Examples of the plating catalyst include metal palladium (Pd), platinum (Pt), silver (Ag), gold (Au), nickel (Ni), cobalt (Co), iron (Fe), and precursors that generate these metals. Among them, palladium, which has high catalytic activity, is preferably used.

Examples of the method for attaching the plating catalyst include a method in which the plating catalyst is first treated with an acidic Pd-Sn colloid solution to be treated under acidic conditions at pH 1 to 3, and then treated with an acid solution. As the acidic catalytic metal colloid solution, a publicly known acidic Pd-Sn colloid catalyst solution or the like can be used, and a commercially available plating process using an acidic catalytic metal colloid solution may be used. Such a process has been systematized and is sold, for example, from Rohm & Haas Electronic Materials LLC.

By such a catalyst attaching treatment, a plating catalyst can be attached to the surface of the substrate 1 to form a plating base 2 as shown in FIG. 1(A).

Alternatively, the plating base can also be formed by printing a desired pattern on the substrate by a publicly known means using a catalyst ink including a plating catalyst as described above.

In the above description, electroless plating is mainly assumed, but the plating of the present embodiment may be performed by, in addition to electroless plating, further electrolytic plating.

The plating base may be formed only on at least a part of the substrate, that is, a portion where a circuit, wiring, or the like is intended to be formed, or may be formed on the entire surface of the substrate. In this case, on one surface of the substrate, a plating catalyst is applied and attached entirely to the surface, or a catalyst ink is printed entirely to the surface. Thereafter, a metal layer is formed on the entire surface by plating treatment, and the metal layer is etched such that a circuit, wiring, or the like in a desired pattern is left by an etching step described later, whereby a circuit, wiring, or the like can be formed.

### Bending Step

Next, the substrate on which the plating base is formed is bent. In the first embodiment, this bending step can be performed using an object, having a bent portion, on which a conductive pattern is to be formed (three-dimensional structure). That is, as depicted in FIG. 1(B), the substrate 1 is bent by laminating the substrate 1 on the bent portion of the object 4 on which a conductive pattern is to be formed.

In the present embodiment, the object on which a conductive pattern is to be formed is not particularly limited as long as it has a bent portion. That is, in the object on which a conductive pattern is to be formed in the present embodiment, at least a part of the conductive pattern forming surface on which a conductive pattern is to be formed is bent. Examples of the object on which a conductive pattern is to be formed include three-dimensional structures having a three-dimensional bent portion, such as plastics and articles thereof; rubber and articles thereof; raw hides and skins, leather, fur skins and articles thereof; saddlery and harness; travel goods, handbags and similar containers; articles of animal gut; wood and articles of wood; wood charcoal; cork and articles of cork; manufactures of straw, of esparto or of other plaiting materials; basketware and wickerwork; pulp of wood or of other fibrous cellulosic material; recovered (waste and scrap) paper or paperboard; paper and paperboard and articles thereof; textiles and textile articles; footwear, headgear, umbrellas, sun umbrellas, walking-sticks, seat-sticks, whips, riding-crops and parts thereof; prepared feathers and articles made therewith; artificial flowers; articles of human hair; articles of stone, plaster, cement, asbestos, mica or similar materials; ceramic products; glass and glassware;

natural or cultured pearls, precious or semi-precious stones, precious metals, metals clad with precious metal, and articles thereof; personal imitation jewelry; coin; base metals and articles of base metals; machinery and mechanical appliances; electrical equipment; parts thereof; sound recorders and reproducers, television image and sound recorders and reproducers, and parts and accessories of such articles; vehicles, aircraft, vessels and associated transport equipment; optical, photographic, cinematographic, measuring, checking, precision, medical or surgical instruments and apparatus; clocks and watches; musical instruments; parts and accessories thereof; furniture; bedding, mattresses, mattress supports, cushions and similar stuffed furnishings; luminaires and lighting fittings including lamps (not elsewhere specified or included); illuminated signs, illuminated name-plates and the like; prefabricated buildings; and toys, games and sports requisites; parts and accessories thereof. By the method for manufacturing a substrate with a conductive pattern of the present embodiment, a circuit or the like can be formed even in such a complicated shape (a shape having a bent portion) without using a mold or the like.

In the present embodiment, even if the object on which a conductive pattern is to be formed is a three-dimensional structure having a three-dimensional bent portion, using a flexible substrate with a plating base formed thereon makes it possible to form a desired circuit, wiring, or the like simply and easily on the object on which a conductive pattern is to be formed without using a mold or the like as illustrated in FIG. 1(B). Even if the flexible substrate extends following the bent portion of the object on which a conductive pattern is to be formed, the extension of the plating base formed of a plating catalyst or a catalyst ink does not greatly affect the subsequent plating, so that it is possible to control disconnection of a circuit, wiring, or the like formed of plating to be formed later.

The means for laminating the substrate on the bent portion of the object on which a conductive pattern is to be formed is not particularly limited, and the lamination can be performed by bonding the surface of the substrate on which surface the plating base is not formed to at least a part or the entire surface of the bent portion. When the substrate contains a thermosetting resin, it is not necessary to use an adhesive or the like for the bonding, and the substrate and the object, having a bent portion, on which a conductive pattern is to be formed can be laminated with superior adhesion by stacking the B-stage substrate and then making the substrate undergo a curing reaction to the C-stage.

In the bending step of the present embodiment, it is preferable that the substrate is stacked and bent on the object on which a conductive pattern is to be formed, and at the same time, the object on which a conductive pattern is to be formed and the substrate are integrated.

### Plating Pretreatment Step

Furthermore, although not shown in drawings, in the present embodiment, a plating pretreatment step of exposing the plating catalyst to the surface may be included before the plating step to be described later, as necessary. The plating pretreatment step makes it possible to perform the plating step properly. The specific pretreatment is not particularly limited, and examples thereof include a treatment of immersing the laminate of the substrate and the object on which a conductive pattern is to be formed obtained as described above in a resin swelling liquid.

### Conductive Pattern Forming Step

Next, by subjecting the laminate of the substrate 1 and the object 4 on which a conductive pattern is to be formed to plating treatment as illustrated in FIG. 1 (C), plating 3 is formed on the plating base 2 and a conductive pattern is formed.

As one example of the plating step, treatment using electroless plating will be described.

First, by subjecting the laminate to electroless plating treatment, an electroless plating film is deposited on a portion of the substrate where a plating base is formed, and the electroless plating film becomes plating of the present embodiment.

As a method of the electroless plating treatment, a method of immersing a substrate partially provided with a plating base in an electroless plating solution to deposit an electroless plating film only on a portion provided with the plating base can be used.

Examples of the metal to be used for electroless plating include copper (Cu), nickel (Ni), cobalt (Co), and aluminum (Al). Among them, plating containing Cu as a main component is preferable from the viewpoint of being superior in conductivity. The case of containing Ni is preferable from the viewpoint of being superior in corrosion resistance and adhesion to solder.

In the present embodiment, the thickness of the plating formed of the electroless plating film is not particularly limited, and can be appropriately set as desired.

In the case of the electrolytic plating treatment, by performing the electrolytic plating treatment after performing the above-described electroless plating treatment, the plating is formed and a desired conductive pattern is formed.

### Etching Step

Although not shown in FIG. 1, the method for forming a conductive pattern of the present embodiment may further include an etching step.

In the etching step, of the plating (plating film) formed by the conductive pattern forming (plating treatment) step described above, a plating film of an unnecessary protruding portion is removed by etching treatment and a conductive pattern by plating is formed.

Specifically, first, the protrusion amount or the amount to be removed of the unnecessary plating film is measured. For the measurement, for example, the height of the plating protrusion protruding from the substrate surface is measured using a confocal laser scanning microscope LEXT OLS3000 manufactured by OLYMPUS Corporation. An amount to be etched is set according to the measurement obtained, and etching treatment is performed. The etching treatment is not particularly limited, but can be performed using an etchant.

The etchant to be used in the present embodiment is preferably an alkaline etchant. Specifically, an alkaline etchant containing an amine compound as a main component and at least hydrogen peroxide water and sulfuric acid can be used. It is considered that the plating film on an overplated portion can be efficiently and easily removed by using such an etchant. The etchant preferably further contains an organic acid. Furthermore, the etchant is preferably a microetching solution.

The etching treatment of the present embodiment can be performed, for example, by spraying the etchant as described above on the substrate. Spraying conditions are not particularly limited as long as the overplated portion can be treated in proper quantities.

By such etching treatment, an excessive or unnecessary plating film can be removed and a highly reliable circuit or the like can be formed.

Alternatively, when the plating base is provided on the entire surface of the substrate in the plating base forming step described above, a circuit or the like can be formed in the etching step by leaving only plating to be a conductive pattern and removing other unnecessary portions by etching. In this case, after the bending step, the plating base is plated by plating treatment to form a metal layer (metal layer forming step), and the metal layer is etched in the etching step to form a circuit or the like having a desired pattern (a step of forming a conductive pattern by etching).

### Component Mounting Step

The manufacturing method of the present embodiment may further include a step of mounting an electronic component that is performed after the conductive pattern is formed. Since the substrate of the present embodiment exerts superior heat resistance, it is superior in component mountability and can withstand heating in a soldering or reflow process.

The component to be mounted is not particularly limited, and examples thereof include various electronic components such as an LED element, a passive element, an active element, an integrated circuit, a display, a motor, a speaker, a piezoelectric element, a switch, a fuse, an antenna, a heat sink, an acceleration sensor, a temperature sensor, a humidity sensor, an optical sensor, an ultrasonic sensor, a pH sensor, a gas sensor, a moving body sensor, an angle sensor, a magnetic sensor, a gyro sensor, a pressure sensor, an orientation sensor, a radiation sensor, a sound sensor, a GPS receiver, and a battery.

The method of mounting an electronic component on the conductive pattern is not particularly limited, and examples thereof include a method using a soldering iron, and a method in which the electronic component is mounted with various component mounting apparatuses after various cream solders are applied, and then mounted by various reflow apparatuses. In particular, it is preferable to use a means for heating only the metal portion by induction heating, microwave, or the like.

As described above, by the method for forming a conductive pattern of the present embodiment, it is possible to form a conductive pattern on a three-dimensional structure having projections and recesses (a bent surface) while controlling disconnection by using a metal material having high conductivity and poor stretchability (a plating/metal layer for forming a circuit, a wiring, a heating wire, or the like). In addition, since the substrate of the present embodiment has flexibility even at room temperature, use of a mold or the like is not essential, and a conductive pattern can be formed by laminating the substrate on the bent portion. That is, in the present embodiment, even when the three-dimensional structure is an object on which a conductive pattern is to be formed, the substrate can be laminated on the object on which a conductive pattern is to be formed, followed by forming a conductive pattern, and then integrating the substrate. In addition, even when the object on which a conductive pattern is to be formed is flexible, there is an advantage that the flexibility is not impaired even after the formation of a conductive pattern.

Therefore, since the method for forming a conductive pattern of the present embodiment can simply and easily form a circuit, wiring, a heating wire, or the like on a three-dimensional structure having projections and recesses (bent portions) and does not impair the flexibility of the three-dimensional structure, the method is very useful for industrial applications. structure, the method is very useful for industrial applications.

### Second Embodiment

As described above, in the method for manufacturing a substrate with a conductive pattern according to the present invention, the use of a mold is not essential, and a substrate with a conductive pattern having a bent portion can be manufactured without using a mold, but on the other hand, it can be manufactured using a mold. Advantages of using the mold include that productivity can be improved and that fine projections and recesses (bent portions) can be formed.

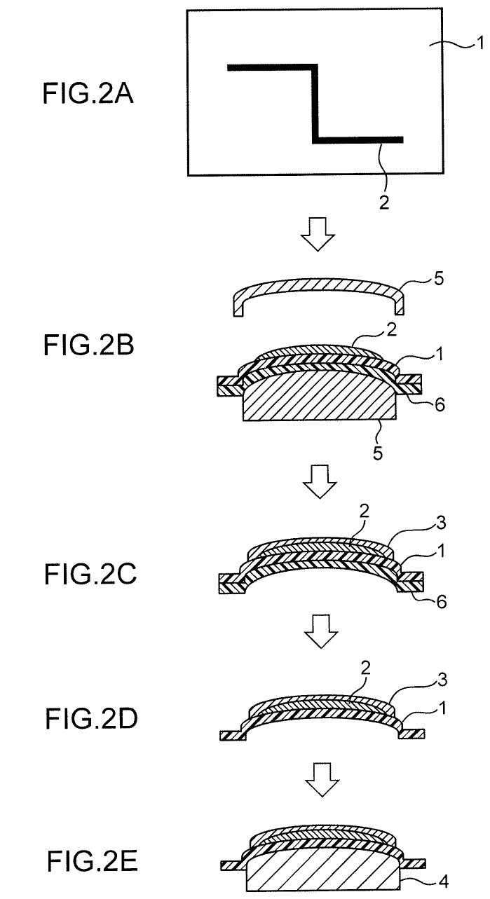

A method for manufacturing a substrate with a conductive pattern in the case of using a mold according to a second embodiment will be described with reference to FIG. 2. Also for the substrate with a conductive pattern according to the second embodiment, the operations up to the plating base forming step (FIG. 2(A)) can be performed similarly to the first embodiment.

Next, in the bending step in the second embodiment, unlike the first embodiment, the substrate is bent using a mold having a bent portion. Specifically, for example, as shown in FIG. 2(B), a mold 5 (an upper mold and a lower mold) having a desired shape is heated to 200° C. and subjected to press treatment from above and below with a prescribed molding load (for example, 1 kN to 2000 kN) to bend the stretchable substrate 1 and three-dimensionally mold the stretchable substrate 1 into the shape of the object 4 on which a conductive pattern is to be formed, which is to be laminated later. If necessary, heating may be performed during the press treatment. When the press treatment is performed, a release liner 6 (for example, made of polyimide) may be used between the mold 5 and the substrate 1.

After the bending, the substrate 1 is removed from the mold 5. Thereafter, a conductive pattern forming step similar to that in the first embodiment is performed (FIG. 2(C)), and then the release liner 6 is released (FIG. 2(D)).

Finally, the substrate 1 on which the plating 3 (conductive pattern) has been formed is bonded to an object 4 on which a conductive pattern is to be formed, and thus a substrate with a conductive pattern can be obtained (FIG. 2(E)). The means for bonding (laminating) the substrate 1 and the object 4 on which a conductive pattern is to be formed is not particularly limited, and the bonding can be performed in the same manner as in the first embodiment.

Further, an etching step and a component mounting step may be included. The etching step and the component mounting step may be performed before bonding to the object 4 on which a conductive pattern is to be formed, or may be performed after bonding to the object 4 on which a conductive pattern is to be formed.

### EXAMPLES

Hereinafter, the present invention will be described more specifically with reference to Examples, but the scope of the present invention is not limited to these.

First, all kinds of materials used in the present Examples are as follows.

### Epoxy Resin

### Epoxy Resin 1

Acrylonitrile as the polymerization unit (a), isobornyl acrylate as the polymerization unit (b), and a polymerization unit (c) represented by the following formula (1) were polymerized such that the blending ratio (polymerization%) of (a):(b):(c) was 10:20:70, and further, glycidyl methacrylate as the polymerization unit (d) was added such that the epoxy equivalent thereof with respect to the total amount of the acrylic resin was the numeral value given in Table 1. After that, the mixture was subjected to a polymerization reaction, affording epoxy resin 1 containing methyl ethyl ketone as a solvent (“PMS-14-67EK40” manufactured by Nagase ChemteX Corporation). The solid ratio was 40% by weight.

### [Chemical Formula 1]

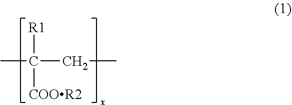 [0094] wherein R1 is hydrogen or a methyl group and R2 is hydrogen or an alkyl group; and X represents an integer.

### Epoxy Resin 2

Epoxy resin 2 (“PMS-14-64EK40” manufactured by Nagase ChemteX Corporation) was obtained in the same manner except that the amount of the polymerization unit (d) of the “PMS-14-67EK40” was changed. The solid ratio was 40% by weight.

### Epoxy Resin 3

Epoxy resin 3 (“PASR-001” manufactured by Nagase ChemteX Corporation) was obtained in the same manner except that the ratio of the polymerization units (a) to (d) of the “PMS-14-67EK40” was changed. The solid ratio was 20%.
Bisphenol-type epoxy resin (“jER1006FS” manufactured by Mitsubishi Chemical Corporation)

### Curing Agent

Acid anhydride curing agent (“RIKACID TBN-100” available from New Japan Chemical Co., Ltd.)
Amine-based curing agent (“POREA SL-100A” manufactured by Kumiai Chemical Industry Co., Ltd.)
Carboxylic acid-based curing agent (“TN-1” manufactured by NOF Corporation)
Phenolic curing agent (“KAYAHARD GPH-103” manufactured by Nippon Kayaku Co., Ltd.)

### Curing Accelerator

Imidazole-based curing accelerator (“2PZ-CN” manufactured by Shikoku Chemicals Corporation)

### Solvent

Methyl ethyl ketone

### <Preparation of Semi-Cured Resin Film>

Resin varnishes 1 to 7 were prepared by adding a solvent (methyl ethyl ketone) to the components at the blended composition (parts by mass) given in Table 1 such that the solid content in the resulting composition was about 40% by mass. After being left at rest and defoamed, each of the resin varnishes 1 to 7 was applied to a PET film (SP-PET O1 manufactured by Mitsui Chemicals Tohcello, Inc.) using a bar coater. Subsequently, heating was performed in an oven at 80° C. for 60 minutes, affording semi-cured resin films 1 to 7.

TABLE 1

| Resin varnish | | Varnish 1 | Varnish 2 | Varnish 3 | Varnish 4 | Varnish 5 | Varnish 6 | Varnish 7 |
|---|---|---|---|---|---|---|---|---|
| Epoxy resin | Epoxy resin 1 | 78.88 | 84.60 | 86.63 | 87.90 | | | |
| | Epoxy resin 2 | | | | | 90.19 | | |
| | Epoxy resin 3 | | | | | | 90.23 | |
| | jER1006FS | | | | | | | 10.82 |
| Curing agent | TBN-100 | 8.05 | | | | 3.53 | 3.52 | 5.02 |
| | SL-100A | | 5.77 | | | | | |
| | TN-1 | | | 8.26 | | | | |
| | GPH-103 | | | | 4.45 | | | |
| Curing accelerator | 2PZ-CN | 0.40 | 0.40 | 0.40 | 0.40 | 0.40 | 0.40 | 0.16 |
| Solvent | Methyl ethyl ketone | 12.67 | 9.24 | 4.71 | 7.26 | 5.89 | 5.86 | 24.00 |

### <Method for Manufacturing Cured Resin Film>

The semi-cured resin films obtained above were each further heated at 180° C. for 60 minutes, affording cured resin films 1 to 7. As cured films of Comparative Examples, polyimide film 1 (“UPILEX-S” manufactured by Ube Industries, Ltd., thickness: 25 μm) and polyurethane film 1 (“DUS 202-CDR” manufactured by Sheedom Co., Ltd., thickness: 100 μm) were also prepared.

### <Evaluation of Semi-Cured Resin Film and Cured Resin Film>

First, for the semi-cured resin films, the thickness of each semi-cured resin film was measured with a micrometer (MDH-25MB manufactured by Mitutoyo Corporation).

### <Methods for Measuring Tensile Modulus and Elongation at Break>

A sample obtained by cutting a substrate sample (a semi-cured resin film or a cured resin film) into a size of 90 mm*5.5 mm was attached to a universal tester (AGS-X manufactured by Shimadzu Corporation), a test was performed at a tensile speed of 500 mm/min, and a tensile modulus was calculated from a stress at an elongation of from 1.0% to 5.0%. In addition, the elongation at the time when the sample was broken was measured.

In this test, the acceptance criteria for each evaluation are 0.1 MPa or more for the tensile modulus and 100% or more for the elongation at break.

### <Method for Evaluating Heat Resistance>

For the cured resin films, the heat resistance was evaluated as follows.

Each of the cured resin films was cut into a 10 mm×30 mm piece and attached to a dynamic viscoelasticity analyzer (DMS6100 manufactured by Seiko Instruments Inc.). A test was performed at a strain amplitude of 10 μm, a frequency of 10 Hz (sine wave), and a heating rate of 5° C./min, and a storage modulus at 250° C. was measured. The acceptance criterion in this test is a storage modulus of 0.1 MPa or more.

The results are summarized in Tables 2 and 3 below.

TABLE 2

| | Semi-cured | Semi-cured | Semi-cured | Semi-cured | Semi-cured | Semi-cured | Semi-cured |
|---|---|---|---|---|---|---|---|
| | film 1 | film 2 | film 3 | film 4 | film 5 | film 6 | film 7 |
| Varnish | Varnish 1 | Varnish 2 | Varnish 3 | Varnish 4 | Varnish 5 | Varnish 6 | Varnish 7 |
| Thickness [μm] | 102 | 99 | 105 | 101 | 103 | 98 | 99 |
| Tensile modulus [MPa] | 10.3 | 2.2 | 7.9 | 18.4 | 1.3 | 92.1 | 145.5 |
| Elongation at break [%] | 739.9 | 798.3 | 683.0 | 712.2 | >1000 | 342.7 | 91.2 |

TABLE 3

| | Cured | Cured | Cured | Cured | Cured | Cured | Cured | Polyimide | Polyurethane |
|---|---|---|---|---|---|---|---|---|---|
| | film 1 | film 2 | film 3 | film 4 | film 5 | film 6 | film 7 | film 1 | film 1 |
| Varnish | Varnish 1 | Varnish 2 | Varnish 3 | Varnish 4 | Varnish 5 | Varnish 6 | Varnish 7 | — | — |
| Tensile modulus [MPa] | 14.3 | 6.6 | 17.4 | 29.8 | 3.0 | 132.1 | 203.5 | 2889.6 | 11.1 |
| Elongation at break [%] | 144.9 | 176.9 | 140.4 | 133.6 | 364.9 | 108.1 | 41.2 | 16.8 | >1000 |
| Storage modulus at | 1.4 | 1.1 | 1.4 | 1.2 | 0.3 | 57 | 230 | 2200 | <0.1 |
| 250° C. [MPa] | | | | | | | | | |

In Tables 2 and 3, “>1000” means that the elongation at break exceeded 1000%, and “<0.1” means that the storage modulus at 250° C. was less than 0.1 MPa.

### <Manufacture of Circuit Board>

### Examples 1 to 7 and Comparative Example 3

### Plating Base Forming Step

The semi-cured resin films 1 to 7 obtained as described above were each placed on a desktop printer (DP-320 manufactured by NEWLONG SEIMITSU KOGYO Co., Ltd.). A palladium particle-containing ink (METALLOID ML-130 manufactured by IOX Co., Ltd.) was printed on a surface of the semi-cured resin film with a screen plate with a desired shape. Then, the ink was dried by heating in an oven at 80° C. for 30 minutes, affording a semi-cured resin film with a base layer.

### Bending Step

Each of the semi-cured resin films with a base layer obtained as described above was attached to a press molding machine. A mold temperature was set to 200° C., and the semi-cured resin film was molded into a hemispherical dome shape at a molding load of 100 kN. Subsequently, the semi-cured resin film was cured by heating at 180° C. for 60 minutes, affording a cured resin molded article with a base layer.

### Pretreatment Step

The cured resin molded article with a base layer obtained as described above was immersed in a resin swelling liquid (CIRCUPOSIT™ CONDITIONER, manufactured by Rohm and Haas Electronic Materials LLC) containing a solvent as a main component for 3 minutes. The liquid temperature was 45° C. Next, the resultant was washed with deionized water.

### Electroless Copper Plating Step

The cured resin molded article with a base layer obtained as described above was immersed in an electroless copper plating solution (CIRCUPOSIT™ Electroless Copper Metallization, manufactured by Rohm and Haas Electronic Materials LLC) for 20 minutes. The liquid temperature was 35° C. Next, the resultant was washed with deionized water, and was left at rest and dried at room temperature. Thereafter, the resultant was subjected to annealing treatment by heating at 80° C. for 60 minutes in an oven, affording a three-dimensional circuit board on which a circuit was formed by copper plating.

### Electrolytic Plating Step

The three-dimensional circuit board obtained as described above was degreased for 10 seconds with an acid washing solution (ACID CLEANER™, manufactured by Rohm and Haas Electronic Materials LLC), and then washed with deionized water. Further, the resultant was subjected to acid washing with sulfuric acid for 10 seconds, and then washed with deionized water. Next, the resultant was immersed in an electrolytic copper plating solution (COPPER GLEAM™ Electrolytic Copper Metallization, manufactured by Rohm and Haas Electronic Materials LLC) for 40 minutes. Next, the resultant was washed with deionized water, and was left at rest and dried at room temperature. Thereafter, the resultant was subjected to annealing treatment by heating at 80° C. for 60 minutes in an oven, affording a three-dimensional circuit board on which a circuit was formed by copper plating.

### Component Mounting Step

A solder paste (S70G-PX TYPE4, manufactured by Senju Metal Industry Co., Ltd.) was applied to the electrode portion of the three-dimensional circuit board obtained as described above, and an LED element (“APA 102-2020” manufactured by Adafruit Industries) was disposed. Subsequently, mounting was performed using an IH reflow system manufactured by Wonder Future Corporation, and the three-dimensional circuit board was peeled off from the PET film, affording a three-dimensional LED module.

### Lamination Step

The three-dimensional LED module obtained as described above was bonded to a rubber ball having the same shape, affording an LED ball.

### Example 7

An LED ball was obtained in the same manner as in Example 1 except that the semi-cured resin film 1 of Example 1 was changed to the cured resin film 1.

### Comparative Example 1

### Plating Base Forming Step

The polyimide film 1 was placed on a desktop printer (DP-320 manufactured by NEWLONG SEIMITSU KOGYO Co., Ltd.). A palladium particle-containing ink (METALLOID ML-130 manufactured by IOX Co., Ltd.) was printed on a surface of the semi-cured resin film with a screen plate with a desired shape. Then, the ink was dried by heating in an oven at 80° C. for 30 minutes, affording a polyimide resin film with a base layer.

### Bending Ste

The polyimide resin film with a base layer obtained as described above was attached to a press molding machine. A mold temperature was set to 280° C., and the polyimide resin film with a base layer was molded into a hemispherical dome shape at a molding load of 1000 kN, affording a polyimide resin molded article with a base layer.

### Electroless Copper Plating Step

The polyimide resin molded article with a base layer obtained as described above was immersed in an electroless copper plating solution (CIRCUPOSIT™ Electroless Copper Metallization, manufactured by Rohm and Haas Electronic Materials LLC) for 20 minutes. The liquid temperature was 35° C. Next, the resultant was washed with deionized water, and was left at rest and dried at room temperature. Thereafter, the resultant was subjected to annealing treatment by heating at 80° C. for 60 minutes in an oven, affording a three-dimensional circuit board on which a circuit was formed by copper plating.

### Electrolytic Plating Step

The three-dimensional circuit board obtained as described above was degreased for 10 seconds with an acid washing solution (ACID CLEANER™, manufactured by Rohm and Haas Electronic Materials LLC), and then washed with deionized water. Further, the resultant was subjected to acid washing with sulfuric acid for 10 seconds, and then washed with deionized water. Next, the resultant was immersed in an electrolytic copper plating solution (COPPER GLEAM™ Electrolytic Copper Metallization, manufactured by Rohm and Haas Electronic Materials LLC) for 40 minutes. Next, the resultant was washed with deionized water, and was left at rest and dried at room temperature. Thereafter, the resultant was subjected to annealing treatment by heating at 80° C. for 60 minutes in an oven, affording a three-dimensional circuit board on which a circuit was formed by copper plating.

### Component Mounting Step

A solder paste (S70G-PX TYPE4, manufactured by Senju Metal Industry Co., Ltd.) was applied to the electrode portion of the three-dimensional circuit board obtained as described above, and an LED element (“APA 102-2020” manufactured by Adafruit Industries) was disposed. Subsequently, mounting was performed using an IH reflow system manufactured by Wonder Future Corporation, affording a three-dimensional LED module.

### Lamination Step

The three-dimensional LED module obtained as described above was bonded to a rubber ball having the same shape, affording an LED ball.

### Comparative Example 2

An LED ball was obtained in the same manner as in Example 1 except that the semi-cured resin film 1 of Example 1 was changed to the polyurethane film 1.

### <Evaluation of Circuit Board>

### Flexibility

Whether or not the flexibility of the LED ball obtained as described above was impaired as compared with that before bonding to the three-dimensional LED module was determined from feeling.

The evaluation criteria were as follows.

Good: Flexibility was not impaired.

Poor: Hardness increased and flexibility was impaired.

### Component Mounting Property

An LED controller and a power supply were connected to the three-dimensional LED module obtained as described above, and the LED was turned on.

The evaluation criteria were as follows.

Good: The LED was turned on properly.

Poor: The LED was not turned on properly, or the substrate was deteriorated.

The results are summarized in Table 4 below.

TABLE 4

| | Example | Example | Example | Example | Example | Example | Example | | | |
|---|---|---|---|---|---|---|---|---|---|---|
| | 1 | 2 | 3 | 4 | 5 | 6 | 7 | Comparative | Comparative | Comparative |
| | Semi- | Semi- | Semi- | Semi- | Semi- | Semi- | Cured | Example 1 | Example 2 | Example 3 |
| | cured | cured | cured | cured | cured | cured | film | Polyimide | Polyurethane | Semi-cured |
| | film 1 | film 2 | film 3 | film 4 | film 5 | film 6 | 1 | film 1 | film 1 | film 7 |
| Flexibility | Good | Good | Good | Good | Good | Good | Good | Poor | Good | Poor |
| Component | Good | Good | Good | Good | Good | Good | Good | Good | Poor | Good |
| packing | | | | | | | | | | |
| property | | | | | | | | | | |

### <Discussion>

It has been confirmed that the method for manufacturing a conductive pattern substrate of the present invention has made it possible to form a circuit board superior in shape followability to an uneven surface and mountability of components.

On the other hand, in Comparative Example 1 using the polyimide film 1, flexibility was impaired because the flexibility of the substrate was insufficient.

Further, in Comparative Example 2 using the polyurethane film 1, component mounting property could not be obtained. This is considered to be because the substrate was poor in heat resistance, deteriorated and deformed during the component mounting step, and component mounting could not be performed properly.

Also in Comparative Example 3 using the semi-cured resin film 7 having an elongation at break of less than 100%, good flexibility could not be obtained.

This application is based on Japanese Patent Application No. 2021-098100 filed on Jun. 11, 2021, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

The method for manufacturing a substrate with a conductive pattern according to the present invention has wide industrial applicability in technical fields such as an optical field, an electronic field, and a medical field, such as wearable devices, patch devices, and flexible display devices.

1. A method for manufacturing a substrate with a conductive pattern, the method comprising:
a base forming step of forming a plating base in a desired pattern on at least a portion of one surface of a stretchable substrate, wherein the stretchable substrate has a tensile modulus at 20° C. of 0.1 MPa or more and 500 MPa or less, an elongation at break of 100% or more and 1000% or less, and a storage modulus at 250° C. of 0.1 MPa or more;
a bending step of bending the stretchable substrate; and
a conductive pattern forming step of plating the plating base after performing the bending step to form a conductive pattern on the stretchable substrate.

2. The method for manufacturing a substrate with a conductive pattern according to claim 1, wherein in the bending step, the stretchable substrate is bent by laminating the stretchable substrate on a bent portion of the object having the bent portion, on which a conductive pattern is to be formed.

3. The method for manufacturing a substrate with a conductive pattern according to claim 1, wherein in the bending step, the stretchable substrate is bent using a mold having a bent portion, and then the stretchable substrate is removed from the mold.

4. The method for manufacturing a substrate with a conductive pattern according to claim 1 wherein the stretchable substrate is formed using a cured product or a semi-cured product of a resin composition containing a thermosetting resin, and the thermosetting resin contains an epoxy resin containing two or more epoxy groups in one molecule.

5. The method for manufacturing a substrate with a conductive pattern according to claim 1, further comprising a step of etching the conductive pattern.

6. A method for manufacturing a substrate with a conductive pattern, the method comprising:
a base forming step of forming a plating base on at least a portion of one surface of a stretchable substrate, wherein the stretchable substrate has a tensile modulus at 20° C. of 0.1 MPa or more and 500 MPa or less, an elongation at break of 100% or more and 1000% or less, and a storage modulus at 250° C. of 0.1 MPa or more;
a bending step of bending the stretchable substrate;
a metal layer forming step of plating the plating base after performing the bending step to form a metal layer; and
a conductive pattern forming step of etching the metal layer to form a conductive pattern.
